(19) United States
(12) Patent Application Publication
(10) Pub. No.: US 2025/0383678 A1
(43) Pub. Date: Dec. 18, 2025

(54) VOLTAGE REGULATOR OUTPUT CURRENT ESTIMATION

(71) Applicant: Qorvo US, Inc., Greensboro, NC (US)

(72) Inventor: Masashi Nogawa, Sachse, TX (US)

(21) Appl. No.: 19/215,554

(22) Filed: May 22, 2025

Related U.S. Application Data
(60) Provisional application No. 63/660,785, filed on Jun. 17, 2024.
(60) Provisional application No. 63/707,466, filed on Oct. 15, 2024.

(51) Int. Cl. G05F 1/569; G01R 19/25; G05F 1/575

(52) U.S. Cl. CPC G05F 1/569; G01R 19/2509; G05F 1/575

(57) ABSTRACT

Voltage regulator output current estimation is disclosed. Herein, the voltage regulator is configured to generate an output current to charge an output capacitor to an output voltage. Specifically, the voltage regulator generates the output current in accordance with a duty cycle signal so generated to track a target of the output voltage. Unlike a conventional voltage regulator wherein a matched direct-current-resistance (DCR) sensing circuit is used to measure the output current (a.k.a. DCR sensing), the voltage regulator disclosed herein emulates the matched DCR sensing circuit with a current emulation circuit. More specifically, the current emulation circuit is configured to estimate the output current based on the duty cycle signal and a set of known parameters. As such, the voltage regulator can overcome many shortcomings associated with the matched DCR sensing circuit for an improved overall performance.

### RELATED APPLICATIONS

This application claims the benefit of U.S. provisional patent application Ser. No. 63/660,785, filed on Jun. 17, 2024, and U.S. provisional patent application Ser. No. 63/707,466, filed on Oct. 15, 2024, the disclosures of which are hereby incorporated herein by reference in their entireties.

### FIELD OF THE DISCLOSURE

The technology of the disclosure relates generally to estimating an output current in a switch-mode voltage regulator in an electronic power system.

### BACKGROUND

Electronic power systems are the enabling infrastructure technology that promotes conversion and distribution of electrical power from a power source to electronics and electrical machines. A power conversion circuit (a.k.a. voltage regulator) is often at the heart of each electronic power system to convert electrical power from raw form and quantity as produced by the power source to an appropriate form and quantity as needed by machines, motors, electronic equipment, and so on.

DC-DC conversion has always been an integral element of switch-mode power supplies that operate by toggling a main switch (e.g., transistor) between on- (a.k.a. closed) and off- (a.k.a. open) states. More specifically, the DC-DC conversion can be carried out by a buck (a.k.a. step-down) converter or a boost (a.k.a. step-up) converter. The buck converter passes energy directly to an output with a power inductor providing continuing current to the output when the main switch is in the off-state, whereas the boost converter stores all the output energy in the power inductor when the main switch is in the on-state and passes the stored energy to the output when the main switch is in the off-state.

### SUMMARY

Aspects disclosed in the detailed description are related to voltage regulator output current estimation. Herein, the voltage regulator is configured to generate an output current to charge an output capacitor to an output voltage. Specifically, the voltage regulator generates the output current in accordance with a duty cycle signal so generated to track a target of the output voltage. Unlike a conventional voltage regulator wherein a matched direct-current-resistance (DCR) sensing circuit is used to measure the output current (a.k.a. DCR sensing), the voltage regulator disclosed herein emulates the matched DCR sensing circuit with a current emulation circuit. More specifically, the current emulation circuit is configured to estimate the output current based on the duty cycle signal and a set of known parameters. As such, the voltage regulator can overcome many shortcomings associated with the matched DCR sensing circuit for an improved overall performance.

In one aspect, a voltage regulator is provided. The voltage regulator includes an output capacitor. The output capacitor is coupled to a voltage output and charged by an output current to provide an output voltage at the voltage output. The voltage regulator also includes a voltage control circuit. The voltage control circuit is configured to determine a target of the output voltage. The voltage regulator also includes a current generation circuit. The current generation circuit is configured to generate a duty cycle signal based on the target of the output voltage and regulate the output current in accordance with the duty cycle signal. The voltage regulator also includes a current emulation circuit. The current emulation circuit is configured to emulate a matched DCR sensing circuit to thereby estimate the output current based on the duty cycle signal.

In another aspect, an electronic power system is provided. The electronic power system includes a voltage regulator. The voltage regulator includes an output capacitor. The output capacitor is coupled to a voltage output and charged by an output current to provide an output voltage at the voltage output. The voltage regulator also includes a voltage control circuit. The voltage control circuit is configured to determine a target of the output voltage. The voltage regulator also includes a current generation circuit. The current generation circuit is configured to generate a duty cycle signal based on the target of the output voltage and regulate the output current in accordance with the duty cycle signal. The voltage regulator also includes a current emulation circuit. The current emulation circuit is configured to emulate a matched DCR sensing circuit to thereby estimate the output current based on the duty cycle signal.

In another aspect, a method for estimating an output current in a voltage regulator is provided. The method includes charging an output capacitor by the output current to provide an output voltage at a voltage output. The method also includes determining a target of the output voltage. The method also includes generating a duty cycle signal based on the target of the output voltage and regulating the output current in accordance with the duty cycle signal. The method also includes emulating a matched DCR sensing circuit to thereby estimate the output current based on the duty cycle signal.

Those skilled in the art will appreciate the scope of the disclosure and realize additional aspects thereof after reading the following detailed description in association with the accompanying drawings.

### BRIEF DESCRIPTION OF THE DRAWINGS

The accompanying drawings incorporated in and forming a part of this specification illustrate several aspects of the disclosure and, together with the description, serve to explain the principles of the disclosure.

FIG. 1 is a schematic diagram of an exemplary existing voltage regulator wherein a matched direct-current-resistance (DCR)sensing circuit is used to measure an output current;

FIG. 2 is a schematic diagram providing an exemplary illustration of the matched DCR sensing circuit in the existing voltage regulator of FIG. 1;

FIG. 3 is a schematic diagram of an exemplary voltage regulator wherein a current emulation circuit is configured according to an embodiment of the present disclosure to estimate an output current;

FIGS. 4A-4C are diagrams providing an exemplary illustration of the current emulation circuit in the voltage regulator of FIG. 2 configured according to various embodiments if the present disclosure;

FIG. 5 is a schematic diagram of an exemplary electronic power system wherein the voltage regulator of FIG. 3 can be provided; and

FIG. 6 is a flowchart of an exemplary process whereby the voltage regulator of FIG. 3 can be configured to estimate the output current.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Aspects disclosed in the detailed description are related to a voltage regulator output current estimation. Herein, the voltage regulator is configured to generate an output current to charge an output capacitor to an output voltage. Specifically, the voltage regulator generates the output current in accordance with a duty cycle signal so generated to track a target of the output voltage. Unlike a conventional voltage regulator wherein a matched direct-current-resistance (DCR) sensing circuit is used to measure the output current (a.k.a. DCR sensing), the voltage regulator disclosed herein emulates the matched DCR sensing circuit with a current emulation circuit. More specifically, the current emulation circuit is configured to estimate the output current based on the duty cycle signal and a set of known parameters. As such, the voltage regulator can overcome many shortcomings associated with the matched DCR sensing circuit for an improved overall performance.

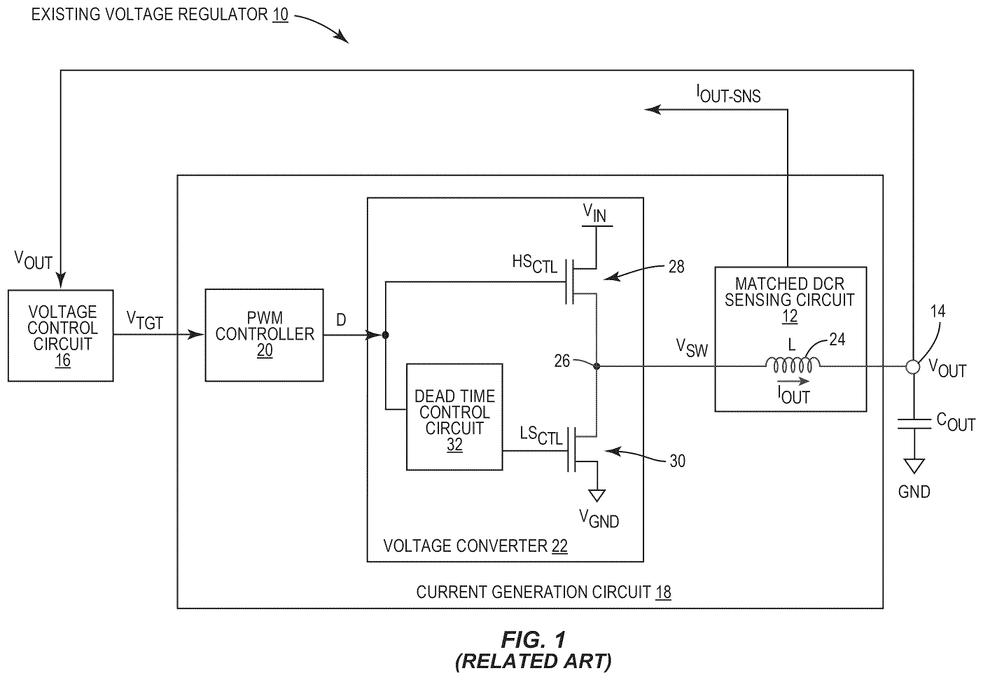

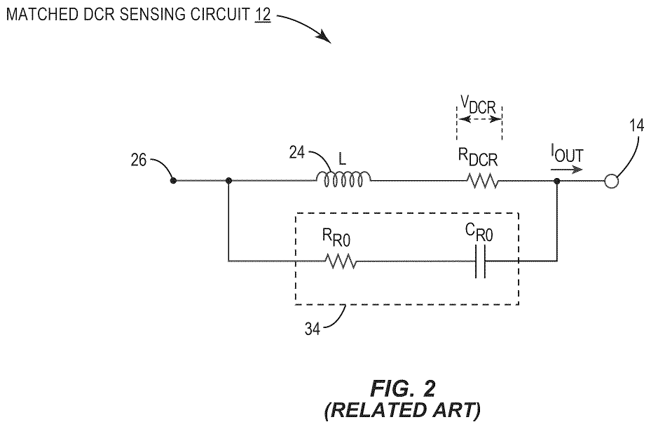

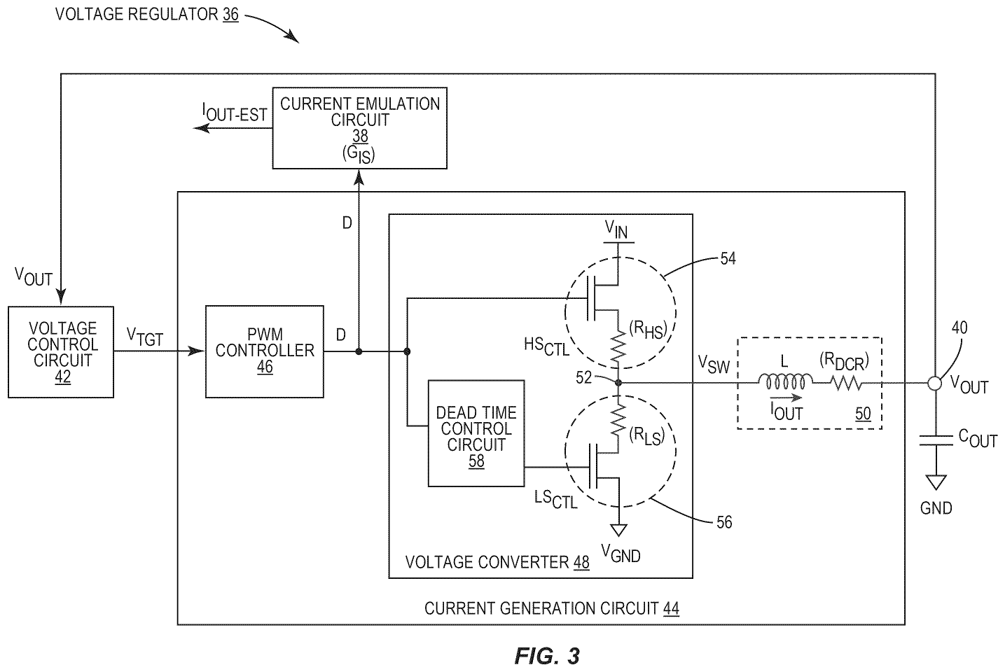

Before discussing the voltage regulator of the present disclosure, starting at FIG. 3, a brief overview of an existing voltage regulator is first provided with reference to FIGS. 1 and 2 to help identify the technical problems to be solved herein.

FIG. 1 is a schematic diagram of an exemplary existing voltage regulator 10 wherein a matched DCR sensing circuit 12 is used to measure an output current I_{OUT}. The existing voltage regulator 10, which may be a switch-mode voltage regulator, includes an output capacitor C_{OUT} that is coupled to a voltage output 14. The output capacitor C_{OUT} can be charged by the output current I_{OUT} to thereby provide an output voltage V_{OUT} at the voltage output 14.

The existing voltage regulator 10 includes a voltage control circuit 16 and a current generation circuit 18. The voltage control circuit 16 is configured to determine a target of the output voltage V_{OUT} (referred to as “target voltage V_{TGT}” hereinafter) that indicates an expected level of the output voltage V_{OUT}. The current generation circuit 18 is configured to generate the output current I_{OUT} to thereby charge the output capacitor C_{OUT} to the output voltage V_{OUT} indicated by the target voltage V_{TGT}.

The current generation circuit 18 includes a pulse-width modulation (PWM) controller 20, a voltage converter 22, and a power inductor 24. The PWM controller 20 is configured to generate a duty cycle signal D in accordance with the target voltage V_{TGT}. The voltage converter 22 is configured to generate a switching voltage V_{SW} at a switching node 26 based on an input voltage V_{IN} and in accordance with the duty cycle signal D. The power inductor 24, which has an inductance L, is coupled between the switching node 26 and the voltage output 14. The power inductor 24 is configured to source the output current I_{OUT} when the switching voltage V_{SW} at the switching node 26 is higher than the output voltage V_{OUT} at the voltage output 14 or sink the output current I_{OUT} when the switching voltage V_{SW} at the switching node 26 is lower than the output voltage V_{OUT}.

Specifically, the voltage converter 22 includes a high-side transistor 28 and a low-side transistor 30. The high-side transistor 28 is coupled between the input voltage V_{IN} and the switching node 26, whereas the low-side transistor 30 is provided between the switching node 26 and a ground voltage V_{GND} (e.g., 0 V). The high-side transistor 28 is biased by a high-side control voltage HS_{CTL}, whereas the low-side transistor 30 is biased by a low-side control voltage LS_{CTL}, which is inverted from the high-side control voltage HS_{CTL} by a dead time control circuit 32.

When the high-side control voltage HS_{CTL} is asserted (e.g., held HIGH), the high-side transistor 28 is turned on to couple the input voltage V_{IN} to the switching node 26. Accordingly, the switching voltage V_{SW} is substantially close to the input voltage V_{IN} (minus the drop voltage of the high-side transistor 28). In the meantime, the low-side control voltage LS_{CTL} is de-asserted (e.g., held LOW) to turn off the low-side transistor 30.

When the high-side control voltage HS_{CTL} is de-asserted (e.g., held LOW), the low-side control voltage LS_{CTL} will be asserted (e.g., held HIGH). Accordingly, the high-side transistor 28 is turned off. In the meantime, the low-side transistor 30 is turned on to couple the ground voltage V_{GND} to the switching node 26. Accordingly, the switching voltage V_{SW} is substantially close to the ground voltage V_{GND} (minus the drop voltage of the low-side transistor 30).

The matched DCR sensing circuit 12 is provided around the power inductor 24 to physically measure the output current I_{OUT} flowing across the power inductor 24 and provide a sensed output current I_{OUT-SNS} to, for example, the voltage control circuit 16 and/or the PWM controller 20 for adjusting the target voltage V_{TGT} and/or the duty cycle signal D. FIG. 2 is a schematic diagram providing an exemplary illustration of the matched DCR sensing circuit 12 in the existing voltage regulator 10 of FIG. 1. Common elements between FIGS. 1 and 2 are shown therein with common element numbers and will not be re-described herein.

The matched DCR sensing circuit 12 has been well-known to people skilled in the field of wireless communication and/or electronic power systems. Specifically, the matched DCR sensing circuit 12 can include the power inductor 24 and a matching circuit 34 that includes a matching capacitor C_{R} and a matching resistor R_{R}. In a way, the matched DCR sensing circuit 12 can be configured to measure the output current I_{OUT} flowing across the power inductor 24 by measuring a voltage V_{DCR} across a parasitic resistor R_{DCR} and then calculate the output current I_{OUT} based on the Ohms Law (L/R_{DCR}=R_{R0}×C_{R0}).

The matched DCR sensing circuit 12 has some inherent shortcomings. In one aspect, as the operating frequency of the existing voltage regulator 10 increases, the time for sensing the output current I_{OUT} from the matching circuit 34 in FIG. 2 may be limited. In another aspect, in an attempt to increase signal amplitude of the output current I_{OUT}, increasing the resistor value R_{DCR} can cause a large amount of power loss. In yet another aspect, it may become increasingly noisy by picking up a tiny amount of the output current I_{OUT} from the matching circuit 34 when the output current I_{OUT} increases substantially. As such, the technical problem to be solved herein is to effectively and accurately estimate the output current I_{OUT} without employing the matched DCR sensing circuit 12.

In this regard, FIG. 3 is a schematic diagram of an exemplary voltage regulator 36 wherein a current emulation circuit 38 is configured according to an embodiment of the present disclosure to replace the matched DCR sensing circuit 12 in FIGS. 1 and 2. As described in detail below, the current emulation circuit 38 is configured to provide an estimated output current I_{OUT-EST} based on a variety of known information. As a result, the voltage regulator 36 can consistently report the output current I_{OUT}, thus solving the technical problem facing the existing voltage regulator 10.

In an embodiment, the voltage regulator 36, which may be a switch-mode voltage regulator, includes an output capacitor C_{OUT} that is coupled to a voltage output 40. The output capacitor C_{OUT} can be charged by the output current I_{OUT} to thereby provide an output voltage V_{OUT} at the voltage output 40. Like the existing voltage regulator 10, the voltage regulator 36 includes a voltage control circuit 42 and a current generation circuit 44. The voltage control circuit 42 is configured to determine a target voltage V_{TGT} that indicates an expected level of the output voltage V_{OUT}. The current generation circuit 44 is configured to generate the output current I_{OUT} to thereby charge the output capacitor C_{OUT} to the output voltage V_{OUT} indicated by the target voltage V_{TGT}.

Besides the current emulation circuit 38, the current generation circuit 44 includes a PWM controller 46, a voltage converter 48, and a power inductor 50. Herein, a resistor R_{DCR} is merely used to represent an inherent resistance of the power inductor 50, as opposed to a physical resistor. The PWM controller 46 is configured to generate a duty cycle signal D in accordance with the target voltage V_{TGT}. In a non-limiting example, the duty cycle signal D includes repeated PWM pulses, each of which has a duration modulated with a high-voltage interval (e.g., a voltage is asserted) and a low-voltage interval (e.g., the voltage is de-asserted). Hereinafter, the duty cycle signal D is said to be ON during the high-voltage interval and OFF during the low-voltage interval.

The voltage converter 48 is configured to generate a switching voltage V_{SW} at a switching node 52 based on an input voltage V_{IN} and in accordance with the duty cycle signal D. The power inductor 50, which has an inductance L, is coupled between the switching node 52 and the voltage output 40. The power inductor 50 is configured to source the output current I_{OUT} when the switching voltage V_{SW} at the switching node 52 is higher than the output voltage V_{OUT} at the voltage output 40 or sink the output current I_{OUT} when the switching voltage V_{SW} at the switching node 52 is lower than the output voltage V_{OUT}.

Specifically, the voltage converter 48 includes a high-side transistor 54 and a low-side transistor 56. The high-side transistor 54 is coupled between the input voltage V_{IN} and the switching node 52, whereas the low-side transistor 56 is provided between the switching node 52 and a ground voltage V_{GND} (e.g., 0 V). The high-side transistor 54 is biased by a high-side control voltage HS_{CTL}, whereas the low-side transistor 56 is biased by a low-side control voltage LS_{CTL}, which is inverted from the high-side control voltage HS_{CTL} by a dead time control circuit 58.

Herein, a resistor R_{HS} is used to merely represent an inherent resistance of the high-side transistor 54, as opposed to being a physical resistor. Likewise, a resistor R_{LS} is used to merely represent an inherent resistance of the low-side transistor 56, as opposed to being a physical resistor.

When the high-side control voltage HS_{CTL} is asserted (e.g., held HIGH), the high-side transistor 54 is turned on to couple the input voltage V_{IN} to the switching node 52. Accordingly, the switching voltage V_{SW} is substantially close to the input voltage V_{IN} (minus the drop voltage of the high-side transistor 54 caused by the inherent high-side resistance R_{HS}). In the meantime, the low-side control voltage LS_{CTL} is de-asserted (e.g., held LOW) to turn off the low-side transistor 56.

When the high-side control voltage HS_{CTL} is de-asserted (e.g., held LOW), the low-side control voltage LS_{CTL} will be asserted (e.g., held HIGH). Accordingly, the high-side transistor 54 is turned off. In the meantime, the low-side transistor 56 is turned on to couple the ground voltage V_{GND} to the switching node 52. Accordingly, the switching voltage V_{SW} is substantially close to the ground voltage V_{GND} (minus the drop voltage of the low-side transistor 56 caused by the inherent low-side resistance R_{LS}).

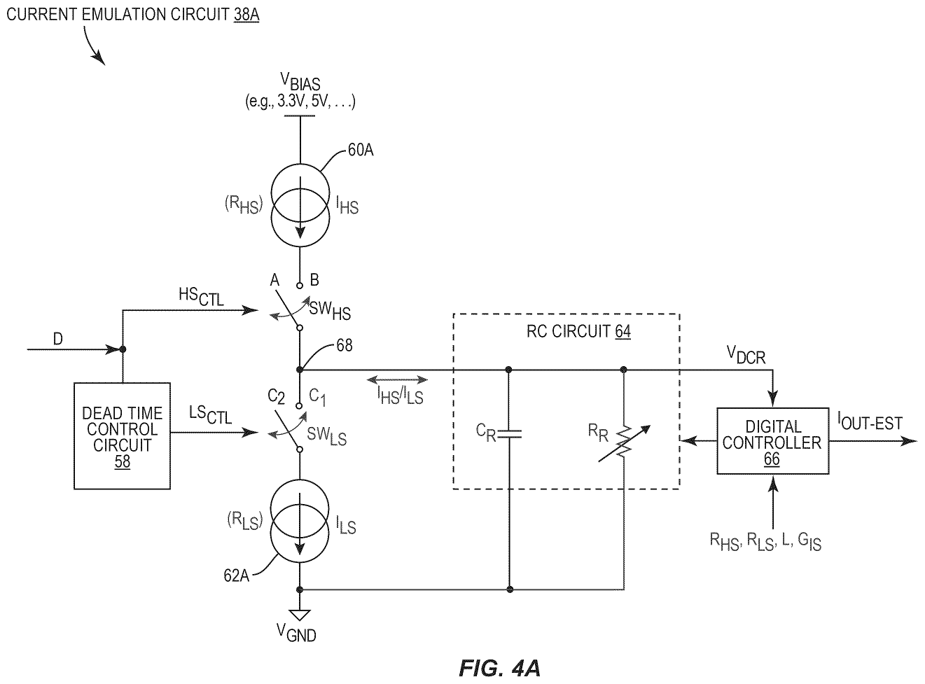

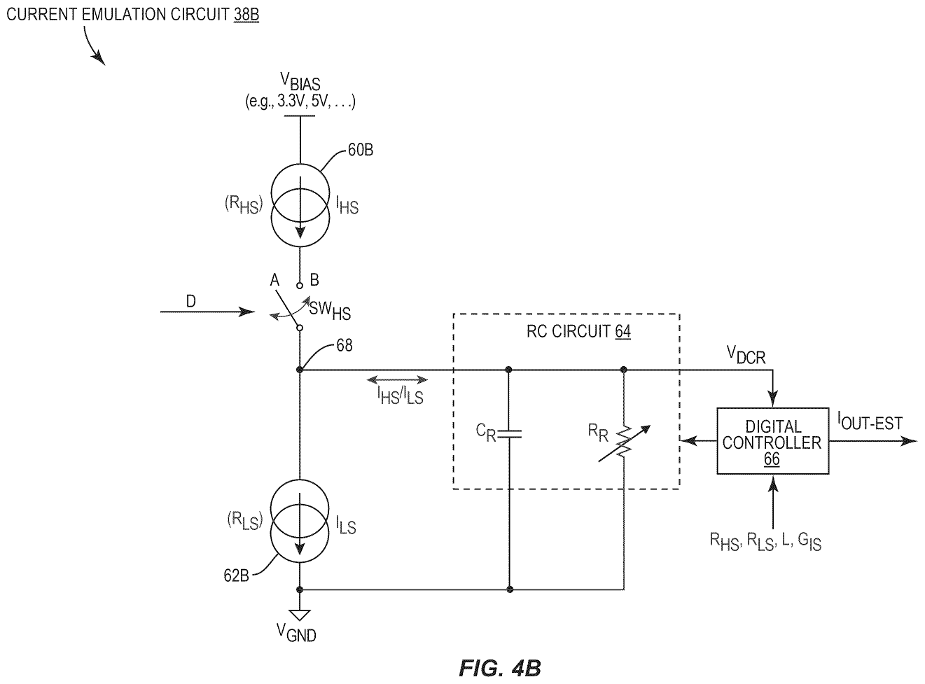

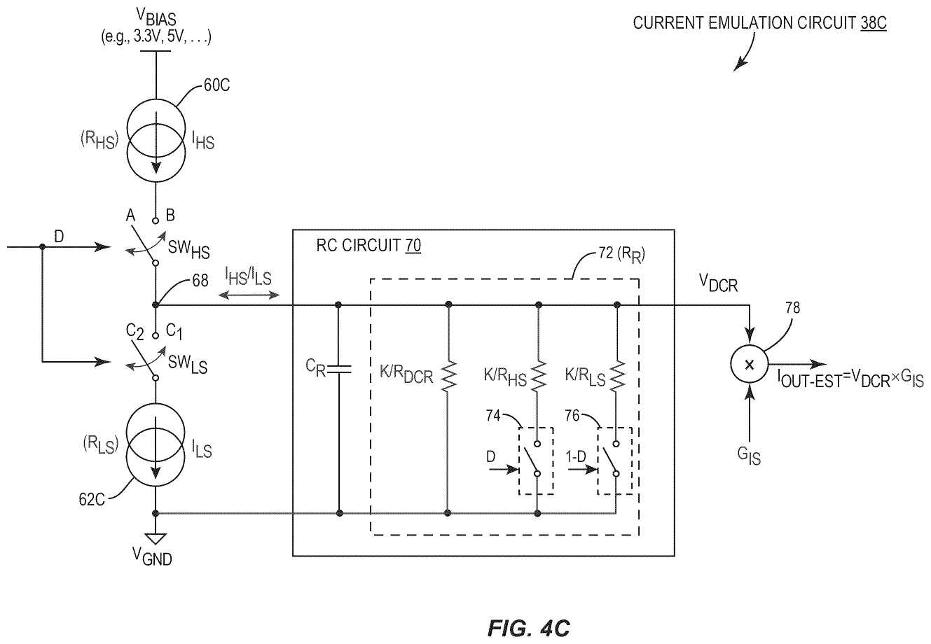

To help understand how the voltage regulator 36 operates, FIGS. 4A-4C are now discussed. FIGS. 4A-4C are schematic diagrams providing an exemplary illustration of the current emulation circuit 38 in FIG. 2 according to various embodiments of the present disclosure. Common elements between FIGS. 3 and 4A-4C are shown therein with common element numbers and will not be re-described herein.

In an embodiment, FIG. 4A illustrates a current emulation circuit 38A that can be provided in the voltage regulator 36 of FIG. 3 to replace the current emulation circuit 38. Specifically, the current emulation circuit 38A includes a high-side current source 60A, a high-side switch SW_{HS}, a low-side current source 62A, a low-side switch SW_{LS}, a resistor-capacitor (RC) circuit 64, and a digital controller 66. The high-side current source 60A is coupled to a bias voltage VBIAS (e.g., 3.3V or 5V). Specifically, an inherent amplitude of the high-side current source 60A is configured to be proportional to a difference between the input voltage V_{IN} and the output voltage V_{OUT} (e.g., V_{IN}−V_{OUT}), so as to emulate the high-side transistor 54 that has an inherent high-side resistance R_{HS}. The high-side switch SW_{HS} is coupled between the high-side current source 60A and an intermediate node 68. Herein, the high-side switch SW_{HS} can be toggled between an open position A and a closed position B by the high-side control voltage HS_{CTL} in the duty cycle signal D.

The low-side switch SW_{LS} is coupled to the intermediate node 68, and the low-side current source 62A is coupled between the low-side switch SW_{LS} and the ground voltage V_{GND} (e.g., 0 V). Herein, an inherent amplitude of the low-side current source 62A is configured to be proportional to the output voltage V_{OUT} so as to emulate the low-side transistor 56 that has an inherent low-side resistance R_{LS}. In an alternative embodiment, both the low-side switch SW_{LS} and the high-side switch SW_{HS} can be individually toggled between the closed positions B and/or C₁ and the open positions A and/or C₂.

At the condition where the low-side switch SW_{LS} is closed and the high-side switch SW_{HS} is open, a low-side current I_{LS} flows out from the RC circuit 64 into the ground voltage V_{GND}. Also, at another condition where while the low-side switch SW_{LS} is opened and the high-side switch SW_{HS} is closed, a high-side current I_{HS} flows into the RC circuit 64. Herein, I_{HS} represents the high-side current flowing through the high-side switch SW_{HS} and I_{LS} represents the low-side current flowing through the low-side switch SW_{LS}. As shown in FIG. 3, the two conditions illustrated herein collectively represent the output current I_{OUT} that flows from the high-side transistor 54 and the low-side transistor 56 into the power inductor 50.

The RC circuit 64, which includes a capacitor C_{R} and an adjustable resistor R_{R}, is coupled between the intermediate node 68 and the ground voltage V_{GND}. Herein, the RC circuit 64 is configured to emulate a voltage V_{DCR} across the parasitic resistor R_{DCR} in FIG. 2 in accordance with an equation (Eq. 1) below.

$$L / {R}_{DCR} = {R}_{R 0} \times {C}_{R 0} = {R}_{R} \times {C}_{R} \qquad ( Eq . 1 )$$

The digital controller 66, in turn, is configured to estimate the output current I_{OUT-EST} based on the voltage V_{DCR} across the parasitic resistance R_{DCR} in accordance with the Ohms Law.

In an embodiment, the digital controller 66 can adjust the adjustable resistor R_{R} to a resistance to thereby emulate the inherent high-side resistance R_{HS} and the inherent low-side resistance R_{LS}. Specifically, the resistance of the adjustable resistor R_{R} can be expressed as in equation (Eq. 2) below.

$${R}_{R} = L / ( {C}_{R} \times [ {R}_{DCR} + {R}_{HS} \times D + {R}_{LS} \times ( 1 - D ) ] ) \qquad ( Eq . 2 )$$

In the equation (Eq. 2), L represents an inductance of the power inductor 50, C_{R} represents a capacitance of the capacitor C_{R}, and R_{DCR} represents a parasitic resistance of the power inductor 50. Accordingly, the digital controller 66 can be further configured to estimate the output current I_{OUT-EST} as in equation (Eq. 3) below.

$${I}_{OUT - EST} = {G}_{IS} \times {V}_{DCR} \qquad ( Eq . 3 )$$

Herein, G_{IS} represents a gain of the current emulation circuit 38. In an embodiment, the inherent high-side resistance R_{HS}, the inherent low-side resistance R_{LS}, the inductance L of the power inductor 50, and/or the gain G_{IS} of the current emulation circuit 38 can all be provided to (or prestored in) the current emulation circuit 38.

In contrast to FIG. 4A, FIG. 4B illustrates a current emulation circuit 38B that can also be provided in the voltage regulator 36 of FIG. 3 to replace the current emulation circuit 38. Specifically, the current emulation circuit 38B includes a high-side current source 60B, the high-side switch SW_{HS}, a low-side current source 62B, the RC circuit 64, and the digital controller 66. Specifically, an inherent amplitude of the high-side current source 60B is configured to be proportional to the input voltage V_{IN} and the low-side current source 62B is configured to be proportional to the output voltage V_{OUT}.

Herein, the low-side current source 62B is configured to emulate the low-side transistor 56 that has an inherent low-side resistance R_{LS}. Specifically, when the high-side switch SW_{HS} is closed, the delta current ΔI (ΔI=I_{HS}−I_{LS}) flows into the RC circuit 64. In contrast, when the high-side switch SW_{HS} is opened, the low-side current I_{LS} flows through the low-side current source 62B.

In an embodiment, the digital controller 66 can adjust the adjustable resistor R_{R} to a resistance to thereby emulate the inherent high-side resistance R_{HS} and the inherent low-side resistance R_{LS}. Specifically, the resistance of the adjustable resistor R_{R} can be expressed as in the equation (Eq. 3).

With reference back to FIG. 3, the inherent high-side resistance R_{HS} and the inherent low-side resistance R_{LS} can cause an error in the estimated output current I_{OUT}-EST. As such, the current emulation circuit 38 needs to take into consideration the inherent high-side resistance R_{HS} and the inherent low-side resistance R_{LS} when estimating the output current I_{OUT}. In this regard, FIG. 4C illustrates a current emulation circuit 38C that can be provided in the voltage regulator 36 of FIG. 3 to replace the current emulation circuit 38. Specifically, the current emulation circuit 38C can take into account the inherent high-side resistance R_{HS} and the inherent low-side resistance R_{LS} when estimating the output current I_{OUT}.

Herein, the current emulation circuit 38C includes a high-side current source 60C, the high-side switch SW_{HS}, a low-side current source 620, the low-side switch SW_{LS}, and a resistor-capacitor (RC) circuit 70. The high-side current source 60C is coupled between a bias voltage VBIAS (e.g., 3.3V or 5V) and the high-side switch SW_{HS}, which is further coupled to the intermediate node 68. Specifically, an inherent amplitude of the high-side current source 60C is configured to be proportional to a difference between the input voltage V_{IN} and the output voltage V_{OUT} (e.g., V_{IN}−V_{OUT}), so as to emulate the high-side transistor 54 that has the inherent high-side resistance R_{HS}. The low-side current source 62C is coupled between the low-side switch SW_{LS} and the ground voltage V_{GND} (e.g., 0 V). Herein, an inherent amplitude of the low-side current source 62C is configured to be proportional to the output voltage V_{OUT} so as to emulate the low-side transistor 56 that has the inherent low-side resistance R_{LS}. When the high-side switch SW_{HS} is closed and the low-side switch SW_{LS} is opened, the high-side current I_{HS} flows into the RC circuit 70. When the high-side switch SW_{HS} is opened and the low-side switch SW_{LS} is closed, the low-side current I_{LS} flows up from the ground voltage V_{GND}.

The RC circuit 70 includes a capacitor C_{R} and a resistor network 72. In an embodiment, the resistor network 72 includes a first resistor K/R_{DCR}, a second resistor K/R_{HS}, and a third resistor K/R_{LS}, wherein K is a scaling factor. The first resistor K/R_{DCR}, which is coupled between the intermediate node 68 and the ground voltage V_{GND}, is configured to emulate the inherent inductor resistance R_{DCR} in FIG. 3. The second resistor K/R_{HS}, which is coupled in series with a first switch 74 between the intermediate node 68 and the ground voltage V_{GND}, is configured to emulate the inherent high-side resistance R_{HS} of the high-side transistor 54 in FIG. 3. The third resistor K/R_{LS}, which is coupled in series with a second switch 76 between the intermediate node 68 and the ground voltage V_{GND}, is configured to emulate the inherent low-side resistance R_{LS} of the low-side transistor 56 in FIG. 3.

The resistor network 72 can be controlled by the duty cycle signal D. Specifically, the first switch 74 is closed to couple the second resistor K/R_{HS} to the ground voltage V_{GND} when the duty cycle signal D is ON, whereas the second switch 76 is closed to couple the third resistor K/R_{LS} to the ground voltage V_{GND} when the duty cycle signal D is OFF. When the duty cycle signal D is ON, the resistor network 72 presents a combined resistance of R_{DCR} and R_{HS}. When the duty cycle signal D is OFF, the resistor network 72 presents a combined resistance of R_{DCR} and R_{LS}. By toggling the first switch 74 and the second switch 76 based on the duty cycle signal D, the resistor network 72 can produce a duty cycle weighted resistance R_{R}, as expressed in equation (Eq. 4).

$${R}_{R} = L / ( {C}_{R} \times [ {R}_{DCR} + {R}_{HS} \times D + {R}_{LS} \times ( 1 - D ) ] ) \qquad ( Eq . 4 )$$

Accordingly, the RC circuit 70 can emulate a voltage V_{DCR} across the parasitic resistor R_{DCR} in FIG. 2. The current emulation circuit 38 may further include a multiplier 78, which determines the estimated load current I_{OUT}-EST as in equation (Eq. 5) below.

$${I}_{OUT - EST} = {G}_{IS} \times {V}_{DCR} \qquad ( Eq . 5 )$$

Herein, G_{IS} represents a gain of the current emulation circuit 38, which can be predetermined and provided (or prestored) in the current emulation circuit 38. Thus, by utilizing the resistor network 72 to account for the inherent high-side resistance R_{HS} and the inherent low-side resistance R_{LS}, the current emulation circuit 38 can produce the estimated load current I_{OUT}-EST more accurately by analog means.

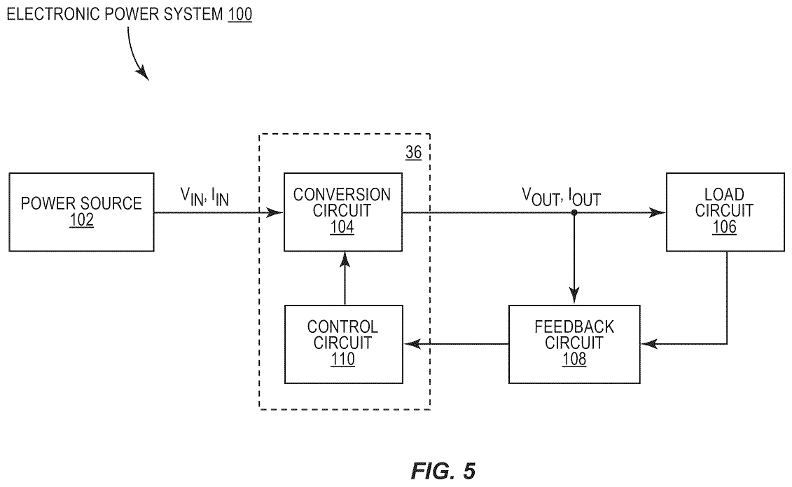

The voltage regulator 36 of FIG. 3, which can include the current emulation circuit 38A of FIG. 4A, the current emulation circuit 38B of FIG. 4B, or the current emulation circuit 38C of FIG. 4C, can be provided in an electronic power system to perform the functionalities described herein. In this regard, FIG. 5 is a schematic diagram of an exemplary electronic power system 100 wherein the voltage regulator 36 of FIG. 3 can be provided.

In an embodiment, the electronic power system 100 includes a power source 102, a conversion circuit 104, a load circuit 106, a feedback circuit 108, and a control circuit 110. The power source 102, which can be an AC or a DC power source, is configured to generate an input voltage V_{IN} and/or an input current I_{IN}.

The conversion circuit 104 is configured to convert the input voltage V_{IN} and/or the input current I_{IN} into an output voltage V_{OUT} and/or an output current I_{OUT}. The conversion circuit 104 may be a step-down converter that converts a higher input voltage V_{IN} and/or a higher input current I_{IN} to a lower output voltage V_{OUT} and/or a lower output current I_{OUT}. The conversion circuit 104 may be a step-up converter that converts a lower input voltage V_{IN} and/or a lower input current I_{IN} to a higher output voltage V_{OUT} and/or a higher output current I_{OUT}. The conversion circuit 104 may also be a step-down and step-up converter that can toggle between step-down and step-up operations in accordance with a duty cycle to produce the output voltage V_{OUT} and/or the output current I_{OUT} at any level.

The load circuit 106 can be any type of electrical circuit, such as an electric vehicle (EV) motor, EV battery, power grid, data center server, and so on. The conversion circuit 104 is configured to provide the output voltage V_{OUT} and/or the output current I_{OUT} to the load circuit 106 via any suitable transmission medium.

The feedback circuit 108 is configured to provide various feedback to the control circuit 110. As an example, the feedback circuit 108 can dynamically measure the output voltage V_{OUT} and/or the output current I_{OUT} being received by the load circuit 106 and report the measurement results to the control circuit 110, either in real time or with hysteresis. The feedback circuit 108 may also monitor operating conditions (e.g., load impedance, operating frequency, thermal temperature, etc.) in the load circuit 106 and report such conditions to the control circuit 110. The control circuit 110, in turn, can dynamically control the conversion circuit 104 to adjust the output voltage V_{OUT} and/or the output current I_{OUT} based on the various feedback provided by the feedback circuit 108.

In an embodiment, the conversion circuit 104 and the control circuit 110 can be replaced by the voltage regulator 36 of FIG. 3. It should be appreciated that the voltage regulator 36 may also be provided in any other circuits in the electronic power system 100.

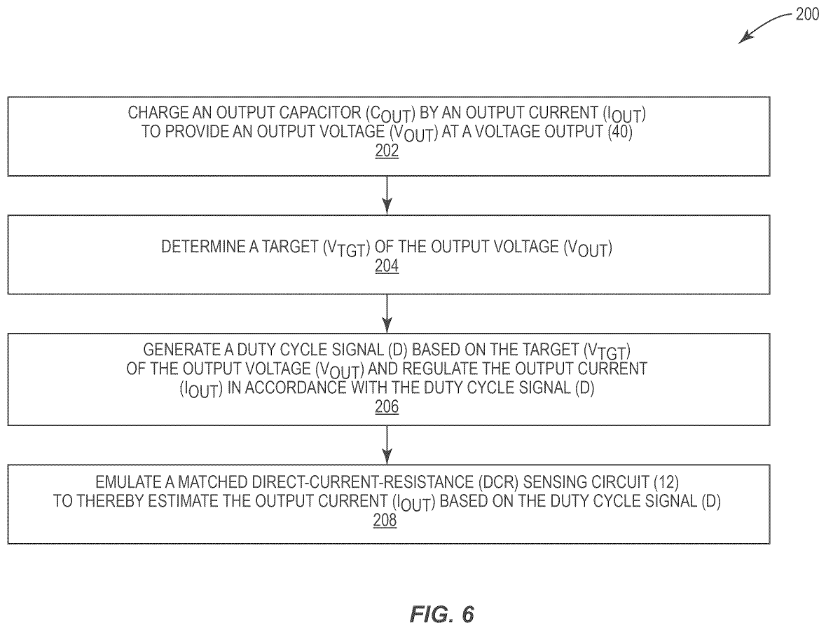

In an embodiment, the voltage regulator 36 of FIG. 3 can be configured to estimate the output current I_{OUT} based on a process. In this regard, FIG. 6 is a flowchart of an exemplary process 200 whereby the voltage regulator 36 of FIG. 3 can be configured to estimate the output current I_{OUT}.

Herein, the process 200 includes charging the output capacitor C_{OUT} by the output current I_{OUT} to provide the output voltage V_{OUT} at the voltage output 40 (step 202). The process 200 also includes determining the target voltage V_{TGT} of the output voltage V_{OUT} (step 204). The process 200 also includes generating the duty cycle signal D based on the target voltage V_{TGT} of the output voltage V_{OUT} and regulating the output current I_{OUT} in accordance with the duty cycle signal D (step 206). The process 200 also includes emulating the matched DCR sensing circuit 12 to thereby estimate the output current I_{OUT} based on the duty cycle signal D (step 208).

Those skilled in the art will recognize improvements and modifications to the embodiments of the present disclosure. All such improvements and modifications are considered within the scope of the concepts disclosed herein and the claims that follow.

What is claimed is:

1. A voltage regulator comprising:
an output capacitor coupled to a voltage output and charged by an output current to provide an output voltage at the voltage output;
a voltage control circuit configured to determine a target of the output voltage;
a current generation circuit configured to generate a duty cycle signal based on the target of the output voltage and regulate the output current in accordance with the duty cycle signal; and
a current emulation circuit configured to emulate a matched direct-current-resistance (DCR) sensing circuit to thereby estimate the output current based on the duty cycle signal.

2. The voltage regulator of claim 1, wherein the current generation circuit comprises:
a pulse-width modulation (PWM) controller configured to generate the duty cycle signal based on the target of the output voltage;
a voltage converter configured to generate a switching voltage at a switching node based on the duty cycle signal; and
a power inductor having an inherent inductor resistance, the power inductor is coupled between the switching node and the voltage output and configured to induce the output current based on the switching voltage.

3. The voltage regulator of claim 2, wherein:
the voltage converter comprises:
a high-side transistor having an inherent high-side resistance and coupled between an input voltage and the switching node; and
a low-side transistor having an inherent low-side resistance and coupled between the switching node and a ground voltage; and
the PWM controller is further configured to generate the duty cycle signal to thereby toggle the switching voltage between the input voltage and the ground voltage.

4. The voltage regulator of claim 3, wherein the current emulation circuit comprises:
a high-side current source and a high-side switch coupled in series between a bias voltage and an intermediate node, the high-side current source is configured to emulate the high-side transistor having the inherent high-side resistance;
a low-side current source and a low-side switch coupled in series between the intermediate node and the ground voltage, the low-side current source is configured to emulate the low-side transistor having the inherent low-side resistance; and
a resistor-capacitor (RC) circuit coupled between the intermediate node and the ground voltage and configured to emulate a voltage across the inherent inductor resistance.

5. The voltage regulator of claim 4, wherein the RC circuit comprises a capacitor and a resistor network coupled in parallel between the intermediate node and the ground voltage, the resistor network is configured to emulate a duty cycle weighted resistance based on the duty cycle signal.

6. The voltage regulator of claim 5, wherein the resistor network comprises:
a first resistor coupled between the intermediate node and the ground voltage and configured to emulate the inherent inductor resistance;
a second resistor coupled in series with a first switch between the intermediate node and the ground voltage and configured to emulate the inherent high-side resistance; and
a third resistor coupled in series with a second switch between the intermediate node and the ground voltage and configured to emulate the inherent low-side resistance.

7. The voltage regulator of claim 6, wherein:
the first switch is closed to couple the second resistor to the ground voltage when the duty cycle signal is ON; and
the second switch is closed to couple the third resistor to the ground voltage when the duty cycle signal is OFF.

8. The voltage regulator of claim 4, wherein the current emulation circuit further comprises a multiplier configured to estimate the output current as expressed as: I_{OUT-EST}=G_{IS}×V_{DCR}, wherein:
I_{OUT-EST} represents the estimated output current;
V_{DCR} represents a voltage across the RC circuit; and
G_{IS} represents a gain of the current emulation circuit.

9. The voltage regulator of claim 3, wherein the current emulation circuit comprises:
a high-side current source coupled to a bias voltage and configured to emulate the high-side transistor having the inherent high-side resistance;
a high-side switch coupled between the high-side current source and an intermediate node and configured to be toggled between an open position and a closed position by the duty cycle signal;
a low-side switch coupled to the intermediate node;
a low-side current source coupled between the low-side switch and the ground voltage and configured to emulate the low-side transistor having the inherent low-side resistance;
a resistor-capacitor (RC) circuit coupled between the intermediate node and the ground voltage and configured to emulate a voltage across the inherent inductor resistance; and
a digital controller configured to estimate the output current based on the voltage across the inherent inductor resistance.

10. The voltage regulator of claim 9, wherein:
the RC circuit comprises a capacitor and an adjustable resistor; and
the digital controller is further configured to adjust the adjustable resistor to a resistance to thereby emulate the inherent high-side resistance and the inherent low-side resistance.

11. The voltage regulator of claim 10, wherein the resistance of the adjustable resistor is expressed as: R_{R}=L/(C_{R}×[R_{DCR}+R_{HS}×D+R_{LS}×(1−D)]), wherein:
R_{R} represents the resistance of the adjustable resistor;
C_{R} represents a capacitance of the capacitor in the RC circuit;
L represents an inductance of the power inductor;
R_{DCR} represents a parasitic resistance of the power inductor;
R_{HS} represents the inherent high-side resistance;
R_{LS} represents the inherent low-side resistance; and
D represents the duty cycle signal.

12. The voltage regulator of claim 10, wherein the digital controller is further configured to estimate the output current as expressed as: I_{OUT-EST}=G_{IS}×V_{DCR}, wherein:
I_{OUT-EST} represents the estimated output current;
V_{DCR} represents a voltage across the RC circuit; and
G_{IS} represents a gain of the current emulation circuit.

13. The voltage regulator of claim 3, wherein the current emulation circuit comprises:
a high-side current source coupled to a bias voltage and configured to emulate the high-side transistor having the inherent high-side resistance;
a high-side switch coupled between the high-side current source and an intermediate node and configured to be toggled between an open position and a closed position by the duty cycle signal;
a low-side current source coupled between the intermediate node and the ground voltage and configured to emulate the low-side transistor having the inherent low-side resistance;
a resistor-capacitor (RC) circuit coupled between the intermediate node and the ground voltage and configured to emulate a voltage across the inherent inductor resistance; and
a digital controller configured to estimate the output current based on the voltage across the inherent inductor resistance.

14. The voltage regulator of claim 13, wherein:
the RC circuit comprises a capacitor and an adjustable resistor; and
the digital controller is further configured to adjust the adjustable resistor to a resistance to thereby emulate the inherent high-side resistance and the inherent low-side resistance.

15. The voltage regulator of claim 14, wherein the resistance of the adjustable resistor is expressed as: R_{R}=L/(C_{R}×[R_{DCR}+R_{HS}×D+R_{LS}×(1−D)]), wherein:
R_{R} represents the resistance of the adjustable resistor;
L represents an inductance of the power inductor;
R_{DCR} represents a parasitic resistance of the power inductor;
R_{HS} represents the inherent high-side resistance;
R_{LS} represents the inherent low-side resistance;
C_{R} represents a capacitance of the capacitor in the RC circuit; and
D represents the duty cycle signal.

16. The voltage regulator of claim 14, wherein the digital controller is further configured to estimate the output current as expressed as: I_{OUT-EST}=L/(R_{R}×G_{IS}/C_{R}), wherein:
I_{OUT-EST} represents the estimated output current;
L represents an inductance of the power inductor;
R_{R} represents the resistance of the adjustable resistor;
C_{R} represents a capacitance of the capacitor; and
G_{IS} represents a gain of the current emulation circuit.

17. An electronic power system comprising a voltage regulator, the voltage regulator comprises:
an output capacitor coupled to a voltage output and charged by an output current to provide an output voltage at the voltage output;
a voltage control circuit configured to determine a target of the output voltage;
a current generation circuit configured to generate a duty cycle signal based on the target of the output voltage and regulate the output current in accordance with the duty cycle signal; and
a current emulation circuit configured to emulate a matched direct-current-resistance (DCR) sensing circuit to thereby estimate the output current based on the duty cycle signal.

18. A method for estimating an output current in a voltage regulator comprising:
charging an output capacitor by the output current to provide an output voltage at a voltage output;
determining a target of the output voltage;
generating a duty cycle signal based on the target of the output voltage and regulating the output current in accordance with the duty cycle signal; and
emulating a matched direct-current-resistance (DCR) sensing circuit to thereby estimate the output current based on the duty cycle signal.

19. The method of claim 18, further comprising:
configuring a pulse-width modulation (PWM) controller to generate the duty cycle signal based on the target of the output voltage;
configuring a voltage converter to generate a switching voltage at a switching node based on the duty cycle signal; and
coupling a power inductor between the switching node and the voltage output to induce the output current based on the switching voltage.

20. The method of claim 19, further comprising:
coupling a high-side transistor between an input voltage and the switching node;
coupling a low-side transistor between the switching node and a ground voltage; and
generating the duty cycle signal to thereby toggle the switching voltage between the input voltage and the ground voltage.
